(19) United States
(12) Patent Application Publication
(10) Pub. No.: US 2018/0212150 A1
(43) Pub. Date: Jul. 26, 2018

(54) ALIGNER STRUCTURE AND ALIGNMENT METHOD

(71) Applicant: Applied Materials, Inc., Santa Clara, CA (US)

(72) Inventor: Saeng Hyun CHO, Gyeonggi-do (KR)

(21) Appl. No.: 15/933,969

(22) Filed: Mar. 23, 2018

Related U.S. Application Data
(62) Division of application No. 15/121,825, filed on Aug. 26, 2016.

(30) Foreign Application Priority Data
Feb. 27, 2014 (KR) 10-2014-0023002
Oct. 10, 2014 (KR) 10-2014-0136990
Oct. 18, 2014 (KR) 10-2014-0141252

(51) Int. Cl. H01L 51/00; C23C 14/04; C23C 16/458; C23C 16/455; C23C 16/04

(52) U.S. Cl. CPC H01L 51/0011; C23C 14/042; C23C 16/4584; C23C 16/4412; C23C 16/45544; C23C 16/042; C23C 16/45551

(57) ABSTRACT

An aligner structure comprises: a first alignment unit for sequentially and firstly aligning the substrate and the mask by the first relative displacement between the substrate and the mask; and a second alignment unit for sequentially and secondarily aligning the substrate and the mask by the second relative displacement between the substrate and the mask after the first alignment by the first alignment unit. The displacement scale of the second relative displacement is smaller than the displacement scale of the first relative displacement so that the substrate and the mask can be quickly and precisely aligned by performing the first relative displacement between the substrate and the mask with a relatively small displacement scale after finishing the first relative displacement between the substrate and the mask with a relatively large displacement scale.

### CROSS-REFERENCE TO RELATED APPLICATIONS

This U.S. non-provisional patent application is a division of, and claims priority to, co-pending U.S. application Ser. No. 15/121,825, filed on Aug. 26, 2016, which claims priority under 35 U.S.C. § 119 of Korean Patent Application Nos. 10-2014-0023002, filed on Feb. 27, 2014, 10-2014-0136990, filed on Oct. 10, 2014, and 10-2014-0141252, filed on Oct. 18, 2014, the entire contents of which are hereby incorporated by reference.

### TECHNICAL FIELD

The present invention disclosed herein relates to a substrate processing apparatus, and more particularly, to an aligner structure and an alignment method for aligning a substrate with a mask to perform a deposition process on a substrate.

### BACKGROUND ART

As the IT technology has remarkably developed and the market of a display such as a smartphone has grown, a flat panel display is being spotlighted.

The flat panel display includes a liquid crystal display, a plasma display panel, and organic light emitting diodes.

Among the above-described flat panel displays, the organic light emitting diodes are being spotlighted as a next generation display device in that it has a quick response speed, power consumption lower than that of a conventional liquid crystal display, a property of lightweight, and high brightness and does not need a separate backlight unit so that it may be manufactured as an ultra slim type.

The organic light emitting diodes uses a principle in which an anode, an organic film, and a cathode are sequentially formed on a substrate, and a voltage is applied between the anode and the cathode to emit light itself.

Although not shown, the organic light emitting diodes are manufactured in such a manner that an anode, a hole injection layer, a hole transfer layer, an emitting layer, an electron transfer layer, an electron injection layer, and a cathode are sequentially formed on the substrate. Here, the anode is made of an indium tin oxide (ITO) having a small surface resistance and an excellent light transmittance.

Also, since the organic film is weak to moisture and oxygen in the air, an encapsulation film encapsulating the organic film or the like to increase a life time of the device is formed on the uppermost portion.

Meanwhile, the anode, the cathode, the organic film, and the encapsulation film are generally formed through a vacuum deposition method to manufacture the organic light emitting diodes.

Here, the vacuum deposition method represents the method in which a source for heating to evaporate a deposition material is installed in a vacuum chamber and the deposition material evaporated from the source is deposited on a surface of a substrate.

In manufacturing the organic light emitting diodes, a mask M is coupled to a substrate S to form the anode, the cathode, and the organic film, which have a predetermined pattern, as shown in FIG. 1. The numerical symbol F in FIG. 1 indicates a support member for closely attaching the mask M to the substrate S, which are aligned by a magnetic force or the like.

Here, the substrate S and the mask M are necessarily aligned with each other to be matched with a pre-designed pattern as shown in FIG. 2. For this, the mask M is displaced by a displacement unit while recognized by a camera to align marks m1 and m2 with each other, which are respectively defined in the substrate S and the mask M, and then the mask M is closely attached to the substrate S by using a support member F.

As the related art, the aligner structure is disclosed in Korean Registered Patent No. 10-0627679.

However, as a resolution of the display increases, a pattern is also micro-sized, and thus further precise alignment between the substrate S and the mask M is necessary to form the micro-pattern.

Also, the precise alignment between the substrate S and the mask M is possible only when micro-displacement of the substrate S or the mask M is realized.

However, since an aligner structure of the related art adopts a mechanical operation method such as a ball screw, the micro-displacement of the substrate S or the mask M is impossible.

Also, since the precise alignment between the substrate S and the mask M is not easily performed through the conventional method adopting the mechanical operation method, the alignment is performed through several times repetition to resultantly increase a time required for aligning the substrate S with the mask M and a total processing time, thereby reducing productivity of the display.

Especially, since the time required for aligning the substrate S with the mask M increases the total processing time to reduce the productivity of the display, the further quick alignment method for the substrate S and the mask M is necessary.

### Disclosure of the Invention Technical Problem

The purpose of the present invention is to provide an aligner structure and an alignment method, which are capable of quickly and precisely aligning a substrate S with a mask M by a combination of first relative displacement between the substrate S and the mask M with a relatively large displacement scale and second relative displacement between the substrate S and the mask M with a relatively small displacement scale.

According to another aspect of the present invention, the purpose of the present invention is to provide an aligner structure and an alignment method, which are capable of quickly performing alignment between the substrate S and the mask M.

### Technical Solution

In accordance with an embodiment of the present invention, an aligner structure that aligns a mask M with a substrate S before performing a thin film deposition process on a surface of the substrate S, the aligner structure includes: a first alignment unit 100 for sequentially and firstly aligning the substrate S with the mask M by first relative displacement between the substrate S and the mask M; and a second alignment unit 200 for sequentially and secondarily aligning the substrate S with the mask M by second relative displacement between the substrate S and the mask M after the first alignment by the first alignment unit 100, wherein a displacement scale of the second relative displacement is less than that of the first relative displacement.

The first alignment unit 100 and the second alignment unit 200 may be coupled to a mask support unit 310 for supporting the mask M and move the mask support unit 310, thereby performing the first relative displacement and the second relative displacement of the mask M supported by the mask support unit 310 with respect to the substrate S.

The first alignment unit 100 and the second alignment unit 200 may be coupled to a substrate support unit 320 for supporting the substrate S and move the substrate support unit 320, thereby performing the first relative displacement and the second relative displacement of the substrate S supported by the substrate support unit 320 with respect to the mask M.

The second alignment unit 200 may be coupled to a mask support unit 310 for supporting the mask M and move the mask support unit 310, thereby performing the second relative displacement of the mask M supported by the mask support unit 310 with respect to the substrate S, and the first alignment unit 100 is coupled to a substrate support unit 320 for supporting the substrate S and move the substrate support unit 320, thereby performing the first relative displacement of the substrate S supported by the substrate support unit 320 with respect to the mask M.

The first alignment unit 100 may be coupled to a mask support unit 310 for supporting the mask M and move the mask support unit 310, thereby performing the first relative displacement of the mask M supported by the mask support unit 310 with respect to the substrate S, and the second alignment unit 200 is coupled to a substrate support unit 320 for supporting the substrate S and move the substrate support unit 320, thereby performing the second relative displacement of the substrate S supported by the substrate support unit 320 with respect to the mask M.

A displacement range of the first relative displacement is 5 μm to 10 μm, and a displacement range of the second relative displacement is desirably 10 nm to 5 μm.

The first alignment unit 100 may be linearly driven by one of a combination of ball screw, a combination of rack and pinion, and a combination of belt and pulley, and the second alignment unit 200 is linearly driven by piezoelectric element.

In accordance with another embodiment of the present invention, an alignment method for aligning a mask M with a substrate S before performing a thin film deposition process on a surface of the substrate S, the alignment method includes: a closely attaching process for closely attaching the substrate S to the mask M; and an alignment process for aligning the substrate S with the mask M. Here, the closely attaching process and the alignment process are performed at the same time.

The closely attaching process for closely attaching the substrate S to the mask M may be performed first, and the closely attaching process and the alignment process may be performed at the same time when a relative distance between the substrate S and the mask M has a predetermined value G.

In accordance with another embodiment of the present invention, an alignment method for aligning a mask M with a substrate S before performing a thin film deposition process on a surface of the substrate S, the alignment method includes: an alignment process for performing alignment between the substrate S and the mask M; a closely attaching process for closely attaching the substrate S to the mask M after the alignment process; an alignment determination measurement process for determining whether an error between the substrate S and the mask M after the closely attaching process is within a predetermined allowable error range E1; and a subsequent alignment process for performing the alignment process and the alignment determination measurement process again after separating the substrate S from the mask M when the error measured from alignment determination measurement process is greater than the allowable error range E₁. Here, when the error measured from the alignment determination measurement process is greater than the allowable error range E₁ and less than an assistant allowable error range E₂. the subsequent alignment process includes an assistant alignment process for performing alignment between the substrate S and the mask M in the state in which the substrate S and the mask M are closely attached to each other.

The assistant alignment process may be performed by relatively and linearly moving the substrate S and the mask M by using piezoelectric element.

The alignment process and the closely attaching process may be performed at the same time.

The closely attaching process for closely attaching the substrate S to the mask M may be performed first, and the closely attaching process and the alignment process may be performed at the same time when a relative distance between the substrate S and the mask M has a predetermined value G.

### Advantageous Effects

The aligner structure according to the present invention may perform the quick and precise alignment between the substrate and the mask by performing the second relative displacement between the substrate S and the mask M with the relatively small displacement scale after finishing the first relative displacement between the substrate S and the mask M with the relatively large displacement scale.

According to another aspect of the present invention, when the closely attaching process and the alignment process are performed at the same time, the alignment method according to the present invention may minimize the time for performing process in comparison with that of the related art which performs the alignment process in the state in which the distance between the substrate S and the mask M is fixed.

According to still another aspect of the present invention, as the alignment between the substrate S and the mask M is performed in the state in which the substrate S and the mask M are closely attached to each other depending on the measurement result when the alignment process between the substrate S and the mask M is performed, the alignment method according to the present invention may further quickly and exactly perform the alignment process.

### BRIEF DESCRIPTION OF THE DRAWINGS

FIG. 1 is a cross-sectional view illustrating a state in which a substrate and a mask are closely attached to each other in a deposition apparatus to perform a deposition process,

FIG. 2 is a partial plan view illustrating an alignment process for the substrate and the mask,

FIG. 3 is a cross-sectional view illustrating an aligner structure according to a first embodiment of the present invention,

FIG. 4 is a partial plan view illustrating a first alignment unit in FIG. 3,

FIG. 5 is a partial side view illustrating a second alignment unit in FIG. 3,

FIG. 6 is a cross-sectional view illustrating an aligner structure according to a second embodiment of the present invention,

FIG. 7 is a cross-sectional view illustrating an aligner structure according to a third embodiment of the present invention,

FIG. 8 is a plan view illustrating an aligner structure according to a fourth embodiment of the present invention,

FIG. 9 is a partial cross-sectional view illustrating the substrate and the mask for performing a substrate alignment method according to the present invention,

FIG. 10 is a partial plan view illustrating an alignment error between the substrate and the mask, and

FIG. 11 is a cross-sectional view illustrating an embodiment of a distance detection unit for detecting a distance between the substrate S and the mask M.

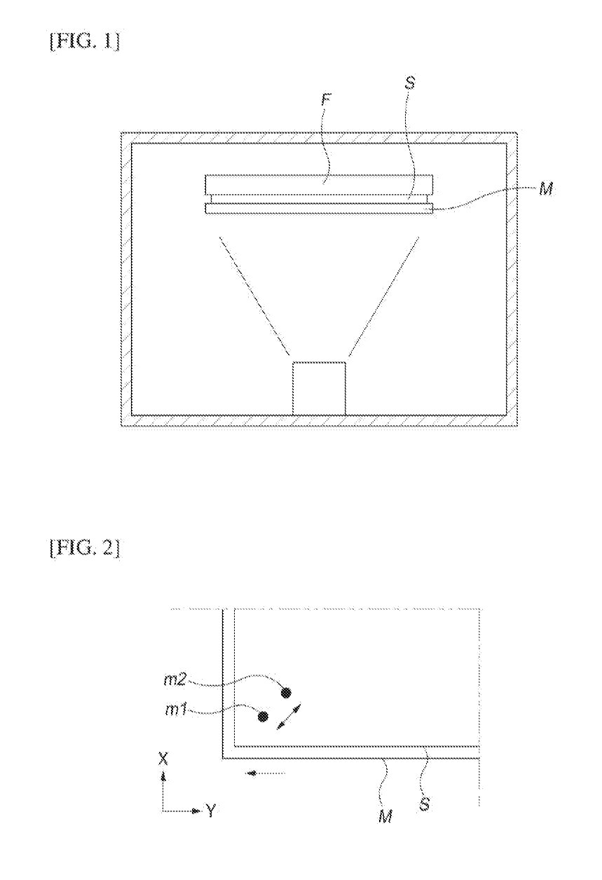

### MODE FOR CARRYING OUT THE INVENTION

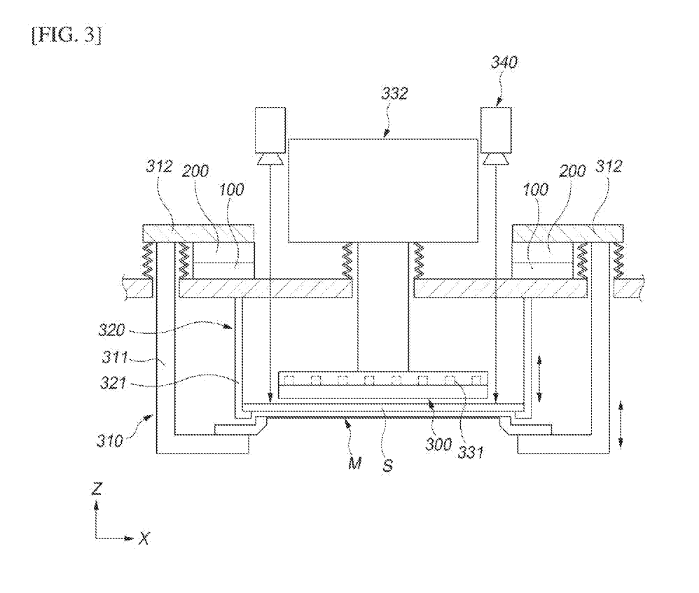

As shown in FIGS. 3 to 7, the aligner structure according to the present invention aligns a mask M with a substrate S before a thin film deposition process is performed on a surface of the substrate S and includes a first alignment unit 100 for sequentially and firstly aligning the substrate S with the mask M by performing first relative displacement between the substrate S and the mask M and a second alignment unit 200 for sequentially and secondarily aligning the substrate S with the mask M by performing second relative displacement between the substrate S and the mask M after the first alignment by the first alignment unit 100.

The aligner structure according to the present invention may be installed in a chamber having an inner space isolated from the outside, which is separated from a deposition apparatus in FIG. 1, or mounted on a frame installed in a clean room having a cleaning environment.

Also, the aligner structure according to the present invention may be installed in the deposition apparatus in FIG. 1 to align the mask M with the substrate S before performing a deposition process.

Meanwhile, the reason for performing the alignment between the substrate S and the mask M by using the first alignment unit 100 and the second alignment unit 200 is to quickly and precisely perform the alignment between the substrate S and the mask M through micro displacement by performing the second displacement M with a relatively small displacement scale after finishing the first displacement with a relatively large displacement scale when the substrate S and the mask M are relatively moved.

That is, a displacement scale of the second relative displacement is desirably less than that of the first relative displacement. For example, it is desirable that a displacement range of the first relative displacement is 5 μm to 10 μm, and a displacement range of the second relative displacement is desirably 10 nm to 5 μm.

Meanwhile, the substrate S and the mask M are supported by a substrate support unit 320 and a mask support unit 310, respectively.

The substrate support unit 320 supports an edge of the substrate S and desirably includes a plurality of support members 321 supporting the edge of the substrate S at a plurality of positions in consideration of size and center of gravity of the substrate S.

The plurality of support members 321 support the edge of the substrates S at the plurality of positions. The plurality of support members 321 may be up-down moved by an up-down movement unit (not shown) in consideration of attachment to the mask M.

The mask support unit 310 supports an edge of the mask M and desirably includes a plurality of support members 311 supporting the edge of the mask M at a plurality of positions in consideration of size and center of gravity of the mask M.

The plurality of support members 311 support the edge of the mask M at the plurality of positions. The plurality of support members 311 may be up-down moved by an up-down movement unit (not shown) in consideration of attachment to the substrate S.

The first alignment unit 100 sequentially and firstly aligns the substrate S with the mask M by the first relative displacement between the substrate S and the mask M.

The first alignment unit 100 may perform the relative displacement between the substrate S and the mask M in various methods. For example, while one of the substrate S and the mask M is fixed, the other is moved, or while both of the substrate S and the mask M are moved, the alignment between the substrate S and the mask M is performed.

Meanwhile, the first alignment unit 100 may be linearly driven by any one of a combination of ball screw, a combination of rack and pinion, and a combination of belt and pulley in consideration of the relatively large scale displacement in the displacement of the substrate S and the mask M.

As an embodiment in which the combination of the ball screw is applied, the first alignment unit 100, as shown in FIG. 3, may include a rotation motor 110, a screw member 130 rotated by the rotation motor 110, a linear movement member 120 coupled to the screw member 130 and linearly moved by the rotation of the screw member 130, and a movement member 140 coupled to the linear movement member 120 to move the substrate S or the mask M by the movement of the linear movement member 120.

Also, the first alignment unit 100 may include the appropriate number of the rotation motor 110, the screw member 130, the linear movement member 120, and the movement member 140 to correct X-axis deviation, Y-axis deviation, and 8-deviation (distortion between the mask and the substrate) with reference to the rectangular substrate S.

In case of an embodiment illustrated in FIGS. 3 and 4, the rotation motor 110, the screw member 130, the linear movement member 120, and the movement member 140 which constitute the first alignment unit 100 are provided in four to correspond to four sides of the mask M.

Also, the movement member 140 may support the second alignment unit 200 for supporting a movement block 312 of the mask support unit 310 and be indirectly coupled to the mask support unit 310.

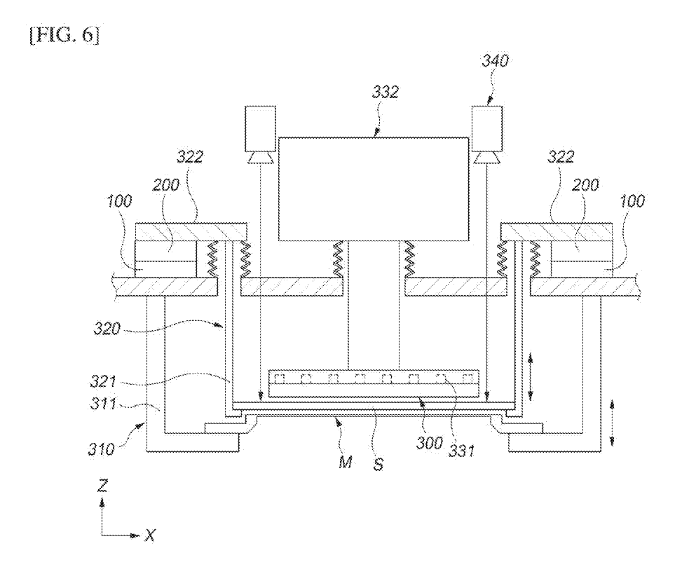

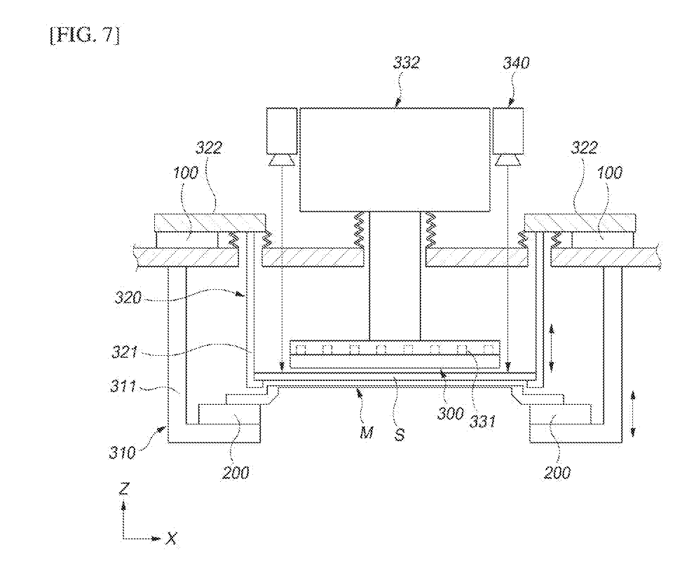

Here, the movement member 140 may have various embodiments according to an object to be moved by the first alignment unit 100. For example, the movement member 140 may be directly or indirectly coupled to the mask support unit 310 or indirectly or directly coupled to the substrate support unit 320 as shown in FIGS. 6 and 7.

The second alignment unit 200 sequentially and secondarily aligns the substrate S with the mask M by the second relative displacement between the substrate S and the mask M after the first alignment by the first alignment unit 100.

The second alignment unit 200 may perform the relative displacement between the substrate S and the mask M in various methods. For example, while one of the substrate S and the mask M is fixed, the other is moved, or while both of the substrate S and the mask M are moved, the alignment between the substrate S and the mask M is performed.

Especially, the second alignment unit 200 is for displacement with a relatively small scale. The second alignment unit 200 may adapt any driving method as long as micro displacement in a range of 10 nm to 5 μm is possible and be desirably linearly-driven by, especially, piezoelectric element.

Since the piezoelectric element may precisely control the linear displacement in the range of 10 nm to 5 μm, the piezoelectric element may be the best solution for correcting micro-deviation between the substrate S and the mask M.

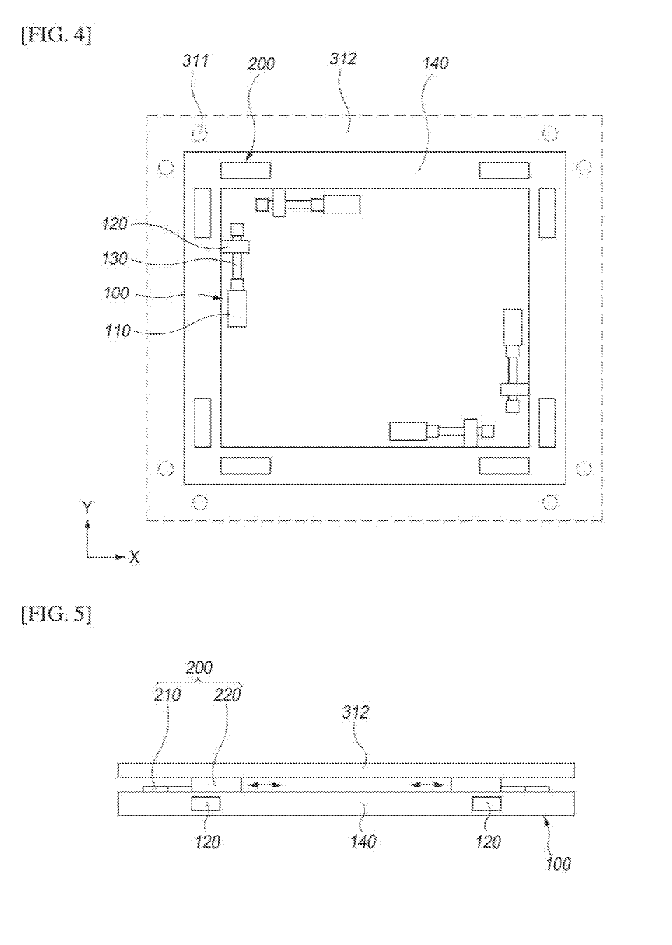

As an embodiment in which the piezoelectric element is applied, as shown in FIG. 5, the second alignment unit 200 may include a linear driving unit 210 for generating a linear driving force by the piezoelectric element and a linear movement member 220 linearly moved by the linear driving force.

Also, the second alignment unit 200 may include the appropriate number of the linear driving unit 210 and the linear movement member 220 to correct X-axis deviation, Y-axis deviation, and 8-deviation (distortion between the mask and the substrate) with reference to the rectangular substrate S.

In case of the embodiment illustrated in FIGS. 3 and 4, the rotation motor 110, the screw member 130, the linear movement member 120, and the movement member 140 which constitute the first alignment unit 100 are installed to correspond to the four sides of the rectangular mask M.

Also, the linear movement member 220 may be directly coupled to the mask support unit 310 for supporting the movement block 312 of the mask support unit 310.

Here, the linear movement member 220 may have various embodiments according to an object to be moved by the second alignment unit 200. For example, the linear movement member 220 may be directly or indirectly coupled to the mask support unit 310 as shown in FIGS. 6 and 7 or indirectly or directly coupled to the substrate support unit 320 although not shown.

As described above, the substrate and the mask may be quickly and precisely aligned with each other by performing the second relative displacement between the substrate S and the mask M with the relatively small displacement scale after finishing the first relative displacement between the substrate S and the mask M with a relatively large displacement scale by virtue of the constitution of the first alignment unit 100 and the second alignment unit 200.

Meanwhile, the above-described constitution of the first alignment unit 100 and the second alignment unit 200 may have various embodiments depending on the position and coupling structure thereof.

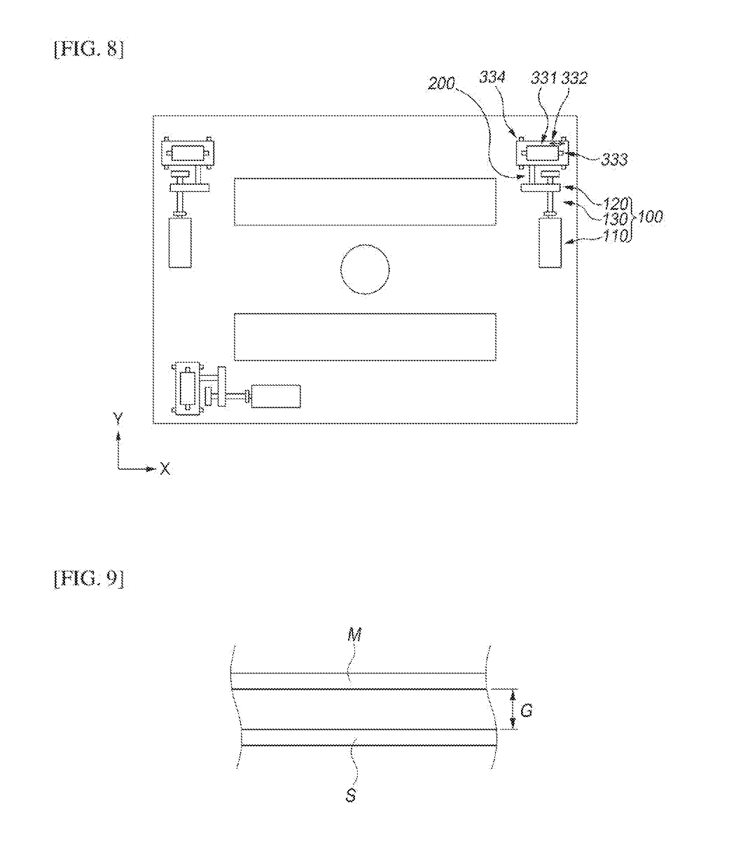

As shown in FIG. 8, in a modified example of the aligner structure according to a first embodiment of the present invention, the aligner structure may include the first alignment unit 100 for driving the first relative displacement and the second alignment unit 200 for driving the second relative displacement after the first relative displacement by the first alignment unit 100.

Also, the first alignment unit 100 may include the rotation motor 110, the screw member 130 rotated by the rotation motor 110, and the linear movement member 120 coupled to the screw member 130 and linearly moved by the rotation of the screw member 130.

Here, the screw member 130 may be rotatably supported by at least one bracket for being stably installed and rotated.

The second alignment unit 200 may include a linear micro-displacement member coupled to the linear movement member 120 so that the second alignment unit 200 is moved together with the first alignment unit 100 and linearly moving the movement block 312 connected to the support member for supporting the substrate S or the mask M.

Especially, the linear micro-displacement member of the second alignment unit 200 desirably includes piezo actuator, i.e., a linear driving module using the piezoelectric element.

The movement block 312 is coupled to the support member for supporting the substrate S or the mask M. The movement block 312 may include any component capable of transmitting the first relative displacement and the second relative displacement of the first alignment unit 100 and the second alignment unit 200 to the substrate S or the mask M.

Meanwhile, to stably perform the first relative displacement and the second relative displacement when the second alignment unit 200 is coupled to the movement block 312, the second alignment unit 200 may include a first support block 332 installed to be movable along at least one first guide rail 334 installed in a chamber or the like and linearly moved by the linear micro-displacement member and the second support block 331 installed to be movable along at least one second guide rail 333 supported by and installed on the first support block 332 to support the movement block 312.

The movement block 312 may be stably supported and the first relative displacement and the second relative displacement may be smoothly performed by the constitution of the first support block 332 and the second support block 331.

The appropriate number, such as three, of the first alignment unit 100 and the second alignment unit 200, which have the above-described constitution, may be installed to correct the X-axis deviation, the Y-axis deviation, and the 8-deviation (distortion between the mask and the substrate) with reference to the rectangular substrate S.

Meanwhile, the first alignment unit 100 and the second alignment unit 200 may have various embodiments depending on the coupling structure and the installation position in the relative displacement between the substrate S and the mask M.

As shown in FIG. 3, in the aligner structure according to the first embodiment of the present invention, the first alignment unit 100 and the second alignment unit 200 may be are coupled to the mask support unit 310 for supporting the mask M and move the mask support unit 310, thereby performing the first relative displacement and the second relative displacement of the mask M supported by the mask support unit 310 with respect to the substrate S.

On the contrary to the first embodiment, as shown in FIG. 6, in an aligner structure according to a second embodiment of the present invention, the first alignment unit 100 and the second alignment unit 200 may be coupled to the substrate support unit 320 for supporting the substrate S and move the substrate support unit 320, thereby performing the first relative displacement and the second relative displacement of the substrate S supported by the substrate support unit 320 with respect to the mask M.

As shown in FIG. 7, in an aligner structure according to a third embodiment of the present invention, the second alignment unit 200 may be coupled to the mask support unit 310 for supporting the mask M and move the mask support unit 310, thereby performing the second relative displacement of the mask M supported by the mask support unit 310 with respect to the substrate S, and the first alignment unit 100 may be coupled to the substrate support unit 320 for supporting the substrate S and move the substrate support unit 320, thereby performing the first relative displacement of the substrate S supported by the substrate support unit 320 with respect to the mask M.

On the contrary to the third embodiment, in an aligner structure according to a fourth embodiment of the present invention, the first alignment unit 100 may be coupled to the mask support unit 310 for supporting the mask M and move the mask support unit 310, thereby performing the first relative displacement of the mask M supported by the mask support unit 310 with respect to the substrate S, and the second alignment unit 220 may be coupled to the substrate support unit 310 for supporting the substrate S and move the substrate support unit 320, thereby performing the second relative displacement of the substrate S supported by the substrate support unit 320 with respect to the mask M.

Meanwhile, although embodiments of the present invention are described when a direction in which the mask M is closely attached to the substrate S is from a lower side to an upper side, the aligner structure according to the present invention may be applied when the direction in which the mask M is closely attached to the substrate S is from the upper side to the lower side and when the mask M is attached in horizontal direction to the substrate S while the substrate S is vertically disposed.

In other words, the aligner structure according to the present invention may be applied when the process is performed in a state in which a surface to be processed of the substrate faces downward, when the process is performed in a state in which the surface to be processed of the substrate faces upward, and when the process is performed in a state in which the surface to be processed of the substrate is perpendicular to the horizontal line.

Reference number 340 indicates a camera for recognizing marks m1 and m2 respectively formed in the substrate S and the mask M, Reference number 300 indicates a support means closely attaching the mask M to support the substrate S by using a plurality of magnets 331 installed therein after the alignment between the substrate S and the mask M, and Reference number 332 indicates a rotation motor rotating the support means 300 for a thin film deposition or the like after the mask M is closely attached to the substrate S. The above-described numerical numbers are not described in FIGS. 3, 6, and 7.

The support means 300 supports the other side of the substrate S to which the mask M is closely attached. The support means 300 may include a carrier moved while supporting the substrate S or a susceptor installed in a vacuum chamber.

As shown in FIG. 11, at least one damping member 120 may be installed on the support means 300 to prevent excessive shock to the substrate S when the mask M is closely attached to the substrate S.

The damping member 120 may be made of flexible material such as rubber.

Also, a plurality of detection sensors 150 may be additionally installed on the support means 300 to detect a distance between the substrate S and the mask M when the substrate S and the mask M are aligned, i.e., arranged.

The detection sensor 150 such as an ultrasonic sensor for detecting a distance may detect the distance between the substrate S and the mask M so that a controller (not shown) of the apparatus determines whether the substrate S and the mask M contact to each other or have an alignable distance.

The above-described detection sensor 150 may transmit a signal to the controller of the apparatus through wireless communications or through wire by a signal transmit member 130 that is separately installed.

Also, the detection sensor 150 may be installed at a plurality of positions to calculate a degree of parallelization between the substrate S and the mask M and control the degree of parallelization between the substrate S and the mask M by a parallelization degree adjustment device (not shown) that will be described later.

As described above, the combination of the first alignment unit 100 and the second alignment unit 200 may have various embodiments depending on the installation position and coupling structure thereof.

Meanwhile, according to an aspect of the present invention, the present invention provides a quick alignment method between the substrate S and the mask M.

In detail, the alignment method according to the present invention includes a closely attaching process for closely attaching the substrate S to the mask M and an alignment process for aligning the substrate S with the mask M. Here, the closely attaching process and the alignment process are performed at the same time.

Especially, the alignment method according to the present invention performs the closely attaching process for closely attaching the substrate S to the mask M first, and, when the relative distance between the substrate S and the mask M has a predetermined value G as shown in FIG. 9, the closely attaching process and the alignment process are desirably performed at the same time.

Here, a distance sensor 150 for detecting a distance between the substrate S and the mask M may be installed in the chamber or the like.

The distance sensor for detecting the distance between the substrate S to the mask M may include any sensor capable of detecting a distance, e.g., an ultrasonic sensor.

As described above, when the closely attaching process and the alignment process are simultaneously performed, a time for performing a process may be minimized in comparison with that of a related art which performs the alignment process in a state in which the distance between the substrate S and the mask M is fixed.

Also, in comparison with the related art that performs the alignment process in a state in which the distance between the substrate S and the mask M is fixed, the alignment process may be further exactly performed because the alignment process is performed in a state in which the distance between the substrate S and the mask M is small.

Also, as the alignment process is quickly and exactly performed, failure of substrate processing may be minimized.

The above-described alignment method according to the present invention may be applied regardless of the alignment structure for alignment between the substrate S and the mask M.

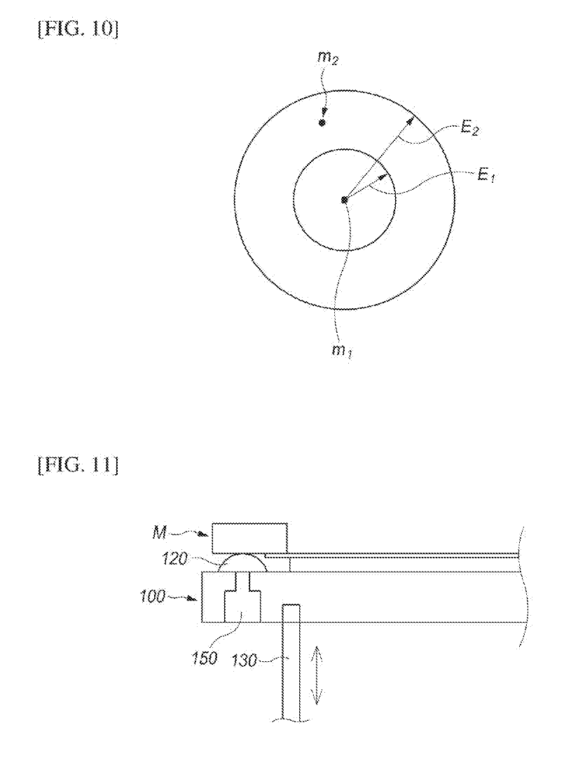

In general, in performing the alignment process for the substrate S and the mask M, the alignment process for the substrate S and the mask M is performed, the closely attaching the substrate S to the mask M and an alignment determination measurement within a predetermined allowable error range E1 are performed (refer to FIG. 10), and, when an error of the result measured from the alignment determination measurement is greater than the allowable error range E1, the substrate S and the mask M are separated again and then the alignment process and the alignment determination measurement are performed again.

However, when the alignment process for the substrate S and the mask M is not smoothly performed, the alignment process and the alignment determination measurement are performed by several times to thereby increase the total time for performing the process.

To solve the above-described problems, the present invention may perform an assistant alignment process for performing the alignment between the substrate S and the mask M in the state in which the substrate S and the mask M are closely attached to each other without separating the substrate S from the mask M when the error measured from the alignment determination measurement is greater than the allowable error range E₁ and less than a predetermined assistant allowable error range E₂.

Here, when the error measured from the alignment determination measurement is greater than the assistant allowable error range E₂, certainly, the substrate S and the mask M are separated from each other again, and then the alignment process and the alignment determination measurement are performed again.

Also, the assistant alignment process is desirably performed by a linear driving device capable of driving linear micro-displacement in consideration of relative linear micro-displacement between the substrate S and the mask M.

Especially, the linear driving device capable of driving the linear micro-displacement may include the above-described piezo actuator.

When the alignment process for the substrate S and the mask M is completed, the substrate S and the mask M, which are closely attached to each other, are chucked by a permanent magnet or the like.

When the alignment process for the substrate S and the mask M is performed as described above, as the alignment between the substrate S and the mask M is performed in the state in which the substrate S and the mask M are closely attached to each other according to the measurement result, the alignment process may be more quickly and exactly performed.

Also, as the alignment process is quickly and exactly performed, the failure of substrate processing may be minimized.

The above-described alignment method according to the present invention may be certainly applied regardless of the alignment structure for alignment between the substrate S to the mask M.

Meanwhile, in the above-described alignment and attachment between the substrate S and the mask M, the substrate S and the mask M are necessary to be parallel to each other.

As the degree of parallelization between the substrate S and the mask M is measured by using the above-described plurality of distance sensors 150 and at least one of the substrate support unit 320 and the mask support unit 310, which respectively support the substrate S and the mask M, is up-down moved by the parallelization degree adjustment device, the substrate S and the mask M may maintain the state parallel to each other.

As the parallelization degree adjustment device up-down moves at least one of the substrate support unit 320 and the mask support unit 310, which respectively support the substrate S and the mask M, the parallelization degree adjustment device controls the state in which the substrate S and the mask M are parallel to each other.

In detail, each of the substrate support unit 320 and the mask support unit 310 includes the plurality of support members 321, 311 supporting the edge of the substrate S and the mask M in a horizontal state and in a plurality of positions of the edge of the substrate S and the mask M. Here, up-down displacement deviation is applied to a portion of the support members 321, 311 disposed on the plurality of positions, so that the state in which the substrate S and the mask M are parallel to each other is controlled.

When the state in which the substrate S and the mask M are parallel to each other is maintained by the above-described parallelization degree adjustment device, the substrate S and the mask M may be precisely aligned with and stably attached to each other.

Especially, the parallelization degree adjustment device may be combined with the first alignment unit 100 and the second alignment unit 200 or installed on the substrate support unit 320 to prevent interference when the first alignment unit 100 and the second alignment unit 200 are installed on the mask support unit 310,

Also, the parallelization degree adjustment device may include all components for up-down linear movement, e.g., a screw jack installed in the vacuum chamber in consideration of up-down ascending/descending operation.

Although the aligner structure and the alignment method according to the present invention are described through an embodiment using the apparatus performing the thin film deposition process, all apparatuses that closely attaching the mask to the substrate to perform the process and requiring the alignment between the substrate and the mask may be applied.

What is claimed is:

1. An alignment method for aligning a mask with a substrate before performing a thin film deposition process on a surface of the substrate, the alignment method comprising:
a closely attaching process for closely attaching the substrate to the mask; and
an alignment process for aligning the substrate with the mask, wherein the closely attaching process and the alignment process are performed at the same time.

2. The alignment method of claim 1, wherein the closely attaching process for closely attaching the substrate to the mask is performed first, and the closely attaching process and the alignment process are performed at the same time when a relative distance between the substrate and the mask has a predetermined value.

3. An alignment method for aligning a mask with a substrate before performing a thin film deposition process on a surface of the substrate, the alignment method comprising:
an alignment process for performing alignment between the substrate and the mask;
a closely attaching process for closely attaching the substrate to the mask after the alignment process;
an alignment determination measurement process for determining whether an error between the substrate and the mask after the closely attaching process is within a predetermined allowable error range; and
a subsequent alignment process for performing the alignment process and the alignment determination measurement process again after separating the substrate from the mask when the error measured from alignment determination measurement process is greater than the allowable error range,
wherein, when the error measured from the alignment determination measurement process is greater than the allowable error range and less than an assistant allowable error range, the subsequent alignment process includes an assistant alignment process for performing alignment between the substrate and the mask in the state in which the substrate and the mask are closely attached to each other.

4. The alignment method of claim 3, wherein the assistant alignment process is performed by relatively and linearly moving the substrate and the mask by using piezoelectric element.

5. The alignment method of claim 3, wherein the alignment process and the closely attaching process are performed at the same time.

6. The alignment method of claim 3, wherein the closely attaching process for closely attaching the substrate to the mask is performed first, and the closely attaching process and the alignment process are performed at the same time when a relative distance between the substrate and the mask has a predetermined value.
